(19) United States
(12) Patent Application Publication
(10) Pub. No.: US 2025/0359238 A1
(43) Pub. Date: Nov. 20, 2025

(54) WAFER AND SEMICONDUCTOR DEVICE

(71) Applicant: KABUSHIKI KAISHA TOSHIBA, Tokyo (JP)

(72) Inventors: Johji NISHIO, Machida Tokyo (JP); Mitsuhiro KUSHIBE, Setagaya Tokyo (JP); Tatsuo SHIMIZU, Shinagawa Tokyo (JP); Chiharu OTA, Kawasaki Kanagawa (JP); Ryosuke IIJIMA, Setagaya Tokyo (JP)

(73) Assignee: KABUSHIKI KAISHA TOSHIBA, Tokyo (JP)

(21) Appl. No.: 19/037,372

(22) Filed: Jan. 27, 2025

(30) Foreign Application Priority Data
May 14, 2024 (JP) 2024-078692

(51) Int. Cl. H10D 62/60; H10D 12/00; H10D 30/66; H10D 62/13; H10D 62/832; H10D 62/834; H10D 64/23

(52) U.S. Cl. CPC H10D 62/60; H10D 12/441; H10D 30/66; H10D 62/145; H10D 62/153; H10D 62/154; H10D 62/8325; H10D 62/834; H10D 64/232; H10D 64/252

(57) ABSTRACT

According to one embodiment, wafer includes a substrate including silicon carbide. The substrate includes a first face and a second face. The substrate includes a first region between the second face and the first face in a first direction from the second face to the first face, a second region between the second face and the first region in the first direction, and a third region between the first region and the first face in the first direction. The substrate includes nitrogen. The first region includes a first element including at least one selected from the group consisting of phosphorus and arsenic. A first concentration of the first element in the first region is higher than a second concentration of the first element in the second region, and higher than a third concentration of the first element in the third region.

### CROSS-REFERENCE TO RELATED APPLICATIONS

This application is based upon and claims the benefit of priority from Japanese Patent Application No. 2024-078692, filed on May 14, 2024; the entire contents of which are incorporated herein by reference.

### FIELD

Embodiments described herein relate generally to a wafer and a semiconductor device.

### BACKGROUND

For example, there are semiconductor devices including silicon carbide. In semiconductor devices, stable characteristics are desired.

### BRIEF DESCRIPTION OF THE DRAWINGS

FIG. 1 is a schematic cross-sectional view illustrating a wafer according to a first embodiment;

FIG. 2 is a graph illustrating the wafer according to the first embodiment;

FIGS. 3A to 3D are schematic plan views illustrating the characteristics of the wafer;

FIG. 4 is a schematic cross-sectional view illustrating a wafer according to the first embodiment; and

FIG. 5 is a schematic cross-sectional view illustrating a semiconductor device according to a second embodiment.

### DETAILED DESCRIPTION

According to one embodiment, wafer includes a substrate including silicon carbide. The substrate includes a first face and a second face. The substrate includes a first region between the second face and the first face in a first direction from the second face to the first face, a second region between the second face and the first region in the first direction, and a third region between the first region and the first face in the first direction. The substrate includes nitrogen. The first region includes a first element including at least one selected from the group consisting of phosphorus and arsenic. A first concentration of the first element in the first region is higher than a second concentration of the first element in the second region, and higher than a third concentration of the first element in the third region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

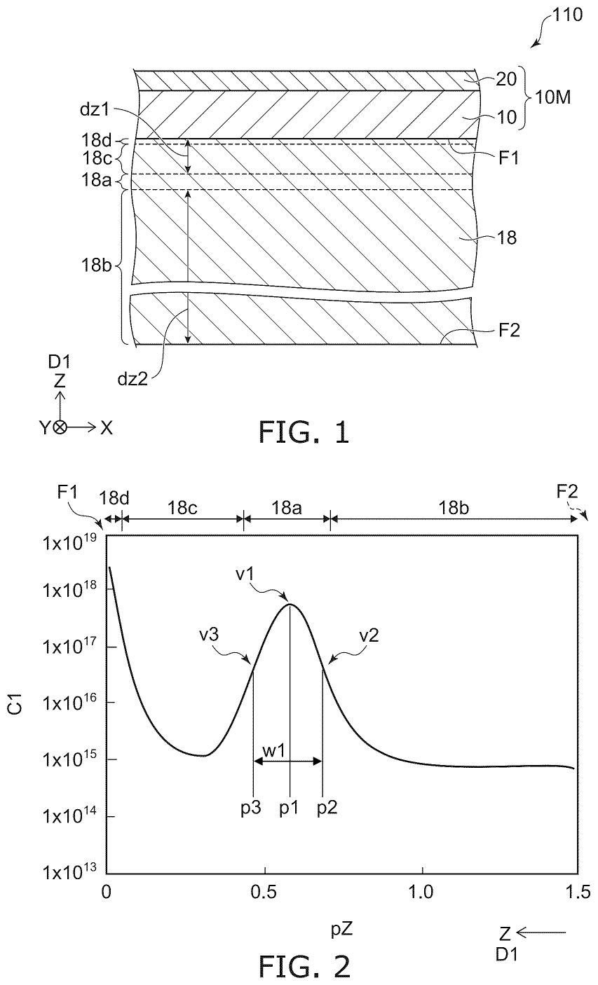

FIG. 1 is a schematic cross-sectional view illustrating a wafer according to a first embodiment.

As shown in FIG. 1, the wafer 110 according to the embodiment includes a substrate 18. The substrate 18 includes silicon carbide (SiC). The substrate 18 is, for example, a silicon carbide bulk substrate. The substrate 18 is, for example, a silicon carbide bulk single crystal substrate. In one example, the silicon carbide included in the substrate 18 is 4H—SiC. The substrate 18 may include 3C—SiC. The conductivity type of the substrate 18 is arbitrary.

The substrate 18 includes a first face F1 and a second face F2. The first face F1 may be, for example, the upper surface. The second face F2 may be, for example, the bottom surface. A first direction D1 from the second face F2 to the first face F1 is defined as a Z-axis direction. One direction perpendicular to the Z-axis direction is defined as an X-axis direction. A direction perpendicular to the Z-axis direction and the X-axis direction is defined as a Y-axis direction. The first face F1 and the second face F2 are, for example, along the X-Y plane. The substrate 18 is along the X-Y plane.

The substrate 18 includes a first region 18a, a second region 18b, and a third region 18c. The first region 18a is located between the second face F2 and the first face F1 in the first direction D1. The second region 18b is located between the second face F2 and the first region 18a in the first direction D1. The third region 18c is located between the first region 18a and the first face F1 in the first direction D1.

In the embodiment, the substrate 18 may further include a fourth region 18d. The fourth region 18d includes the first face F1. The third region 18c is located between the first region 18a and the fourth region 18d in the first direction D1.

In the embodiment, the substrate 18 satisfies a first condition or a second condition. In the first condition, the substrate 18 includes nitrogen. In the first condition, the substrate 18 is of n-type. In the first condition, the first region 18a includes a first element including at least one selected from the group consisting of phosphorus and arsenic.

In the first condition, a concentration (first concentration) of the first element in the first region 18a is higher than a concentration (second concentration) of the first element in the second region 18b, and is higher than a concentration (third concentration) of the first element in the third region 18c. The first region 18a is a region where the concentration of the first element is locally maximum in the first direction D1.

In the second condition, the substrate 18 includes aluminum. In the second condition, the substrate 18 is of p-type. In the second condition, the first region 18a includes a second element including at least one selected from the group consisting of gallium and indium.

In the second condition, a concentration (first concentration) of the second element in the first region 18a is higher than a concentration (second concentration) of the second element in the second region 18b, and higher than a concentration (third concentration) of the second element in the third region 18c. The first region 18a is a region where the concentration of the second element is locally maximum in the first direction D1.

By providing such a first region 18a, for example, expansion of stacking faults can be suppressed. Thereby, a wafer whose characteristics can be stabilized can be provided.

FIG. 2 is a graph illustrating the wafer according to the first embodiment.

The horizontal axis in FIG. 2 is the position pZ in the Z-axis direction. The vertical axis is the concentration C1 of the first element or the second element. Hereinafter, a case will be described in which the substrate 18 satisfies the first condition and the first region 18a includes the first element.

As shown in FIG. 2, the first concentration of the first element (At least one selected from the group consisting of phosphorus and arsenic) in the first region 18a is higher than the second concentration of the first element in the second region 18b. The first concentration is higher than the third concentration of the first element in the third region 18c.

For example, the substrate 18 includes a first position p1, a second position p2, and a third position p3. The first position p1 is included in the first region 18a. The second position p2 is located between the second face F2 and the first position p1 in the first direction D1. The third position p3 is located between the first position p1 and the first face F1 in the first direction D1.

In the first direction D1, the concentration of the first element in the substrate 18 is at a first peak value v1 at the first position p1. The concentration v2 of the first element at the second position p2 is 1/10 of the first peak value v1. The concentration v3 of the first element at the third position p3 is 1/10 of the first peak value v1. In this example, the distance w1 along the first direction D1 between the second position p2 and the third position p3 is not less than 0.2 μm and not more than 0.4 μm. In one example, the first peak value v1 (peak value of concentration of the first element) may be not less than 1×10¹⁶ cm⁻³ and not more than 1×10¹⁸ cm⁻³. In the case where the substrate 18 satisfies the first condition, the concentration of nitrogen in the substrate 18 may be not less than 5×10¹⁸ cm⁻³ and not more than 1×10¹⁹ cm⁻³.

Thus, by providing the first region 18a where the concentration of the first element is locally high, it is thought that, for example, the first element terminates the dangling bond of Si. Thereby, the movement of defects is suppressed. In the case where the substrate 18 includes nitrogen, the first element having an atomic weight larger than nitrogen is locally introduced. It is thought that the movement of defects is effectively suppressed by the first element having a large atomic weight.

The concentration of the first element (first concentration) in the first region 18a may be 50 times or more the concentration (third concentration) of the first element in the third region 18c.

In FIG. 2, the substrate 18 satisfies the second condition, and the first region 18a may include the second element (at least one selected from the group consisting of gallium and indium). In this case, the vertical axis in FIG. 2 is the concentration C1 of the second element. In this case, in the first direction D1, the concentration of the second element in the substrate 18 is at the first peak value v1 at the first position p1. The concentration v2 of the second element at the second position p2 is 1/10 of the first peak value v1. The concentration v3 of the second element at the third position p3 is 1/10 of the first peak value v1. In this example, the distance w1 along the first direction D1 between the second position p2 and the third position p3 is not less than 0.2 μm and not more than 0.4 μm. In one example, the first peak value v1 (peak value of the concentration of the second element) may be not less than 1×10¹⁶ cm⁻³ and not more than 1×10¹⁸ cm⁻³. In the case where the substrate 18 satisfies the second condition, the aluminum concentration in the substrate 18 may be not less than 1×10¹⁸ cm⁻³ and not more than 5×10¹⁸ cm⁻³.

Thus, by providing the first region 18a where the concentration of the second element is locally high, the second element is considered to terminate the dangling bond of Si, for example. Thereby, the movement of defects is suppressed. In the case where the substrate 18 including aluminum, the second element having atomic weight larger than that of aluminum is locally introduced. It is thought that the movement of defects is effectively suppressed by the second element having a large atomic weight.

The concentration of the second element (first concentration) in the first region 18a may be 50 times or more the concentration of the second element (third concentration) in the third region 18c.

For example, the first element or the second element is implanted near the surface of the substrate 18. The high temperature treatment causes the first element or the second element to move from inter-lattice positions to lattice positions. The high-temperature treatment may be heat treatment when epitaxially growing a silicon carbide layer on the substrate 18. The first element or the second element that has moved from the inter-lattice position to the lattice position terminates the Si dangling bond. For example, the movement (migration) of partial dislocations with Si-core is inhibited. Thereby, for example, replication of stacking faults during epitaxial growth is suppressed. For example, single Shockley stacking faults (1SSF) are effectively suppressed. For example, double Shockley stacking faults (2SSF) are effectively suppressed. For example, intrinsic Frank stacking faults (IFSF) are effectively suppressed.

In the embodiment, for example, in the case where the first region 18a includes the first element, the first region 18a may include a bond between the first element and silicon. In this case, the first region 18a includes at least one of a bond between phosphorus and silicon, and a bond between arsenic and silicon. These bonds suppress the propagation of defects, for example.

For example, in the case where the first region 18a includes the second element, the first region 18a includes a bond between the second element and silicon. In this case, the first region 18a includes at least one of a bond between gallium and silicon, or a bond between indium and silicon. These bonds suppress the propagation of defects, for example.

As shown in FIG. 1, a first distance dz1 between the first region 18a and the first face F1 may be shorter than a second distance dz2 between the second face F2 and the first region 18a. For example, the first element or the second element can be efficiently implanted from the first face F1. The first region 18a where the concentration of the first element or the second element is locally high can be stably obtained.

As shown in FIGS. 1 and 2, the substrate 18 may further include a fourth region 18d. The fourth region 18d includes the first face F1. The third region 18c is located between the first region 18a and the fourth region 18d in the first direction D1.

In the case where the substrate 18 satisfies the first condition, the concentration of the first element (fourth concentration) in the fourth region 18d may be higher than the concentration of the first element (third concentration) in the third region 18c.

In the case where the substrate 18 satisfies the second condition, the concentration of the second element (fourth concentration) in the fourth region 18d may be higher than the concentration of the second element (third concentration) in the third region 18c.

For example, when the first element or the second element is implanted into the first region 18a by ion implantation or the like, the first element or the second element may be segregated on the surface (first face F1). For example, the excess first element or second element present between the lattices may be diffused and segregated toward the surface. As a result, the fourth region 18d having a high concentration of the first element or the second element may be generated. For example, the first element or the second element segregated on the surface of the substrate 18 exhibits a surface step smoothing effect (surfactant effect) during epitaxial growth. Thereby, the occurrence of basal plane dislocations at the start of epitaxial growth is suppressed.

The maximum value of the concentration of the first element (fourth concentration) in the fourth region 18d may be higher than the concentration of the first element (first concentration) in the first region 18a. The fourth concentration may be lower than or equal to the first concentration.

The maximum value of the concentration of the second element (fourth concentration) in the fourth region 18d may be higher than the concentration of the second element (first concentration) in the first region 18a. The fourth concentration may be lower than or equal to the first concentration.

The first element or the second element contributes to dangling bond termination of Si and does not need to substantially affect conductivity.

As shown in FIG. 1, wafer 110 may further include silicon carbide member 10M. The silicon carbide member 10M is epitaxially grown on substrate 18, for example. The silicon carbide member 10M may include first silicon carbide region 10 including a third element. The third element includes at least one selected from the group consisting of nitrogen, phosphorus, and arsenic. The first face F1 is between the second face F2 and the first silicon carbide region 10. A concentration of the third element in first silicon carbide region 10 may be, for example, not less than 1×10¹⁴ cm⁻³ and not more than 1×10¹⁶ cm⁻³. In the case where the substrate 18 satisfies the first condition, the concentration of nitrogen in the substrate 18 may be higher than the concentration of the third element in first silicon carbide region 10.

The silicon carbide member 10M may further include a second silicon carbide region 20 including a fourth element. The first silicon carbide region 10 is located between the substrate 18 and the second silicon carbide region 20 in first direction D1. The fourth element includes at least one selected from the group consisting of boron, aluminum, and gallium. A concentration of the fourth element in second silicon carbide region 20 may be, for example, not less than 5×10¹⁷ cm⁻³ and not more than 1×10²⁰ cm⁻³.

For example, the substrate 18 includes basal plane dislocations (BPDs). The BPDs occur in first silicon carbide region 10 based on BPDs in the substrate 18. During operation of the semiconductor device, stacking faults expand from BPDs in the first silicon carbide region 10. The stacking fault is, for example, a single Shockley stacking fault.

For example, when holes are injected into an n-type silicon carbide semiconductor element, stacking faults starting from BPD expand. As a result, forward characteristics tend to deteriorate. Furthermore, when partial dislocations of stacking faults reach the p-type semiconductor region, leakage current increases in the reverse characteristics. This causes a breakdown voltage failure.

In the embodiment, by providing the first region 18a on the substrate 18, expansion of stacking faults starting from BPDs can be suppressed. Thereby, deterioration of characteristics due to expansion of stacking faults can be suppressed. According to the embodiment, a semiconductor device whose characteristics can be stabilized can be provided.

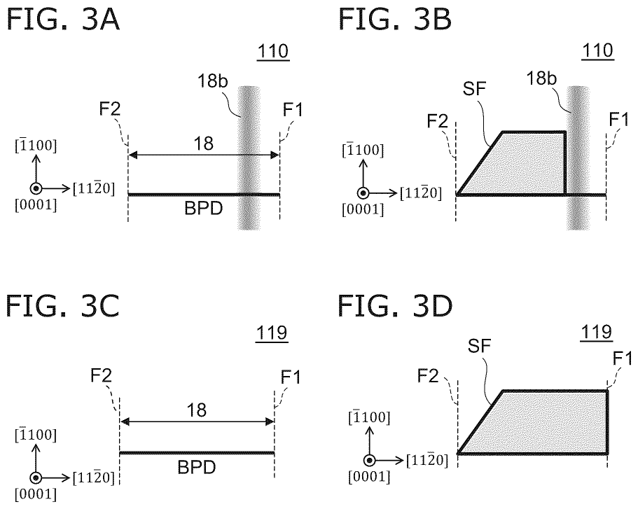

FIGS. 3A to 3D are schematic plan views illustrating the characteristics of the wafer.

FIGS. 3A and 3B correspond to the wafer 110 according to the embodiment. FIGS. 3C and 3D correspond to a wafer 119 of a reference example. In the wafer 119, the substrate 18 is not provided with the first region 18a including the first element. These figures schematically illustrate photoluminescence images. By irradiating the wafer with ultraviolet light, it can be determined whether BPDs will expand into stacking faults. FIGS. 3A and 3C correspond to the state before ultraviolet light irradiation. FIGS. 3B and 3D correspond to the state after ultraviolet light irradiation.

As shown in FIGS. 3C and 3D, in the wafer 119 of the reference example, the stacking fault SF based on the BPD expands due to ultraviolet light irradiation.

On the other hand, as shown in FIGS. 3A and 3B, in the wafer 110 according to the embodiment, although the stacking fault SF expands when ultraviolet light is irradiated, the stacking fault SF does not extend beyond the first region 18a. In the embodiment, the stacking fault SF is suppressed from reaching the silicon carbide member 10M. Leakage current path is suppressed. Thereby, stable characteristics can be provided.

In the embodiment, the stacking fault SF is expanded in the second region 18b below the first region 18a by at least one of voltage application or ultraviolet irradiation. On the other hand, in the third region 18c above the first region 18a, the stacking fault SF does not substantially expand due to the at least one of voltage application or ultraviolet irradiation.

As shown in FIG. 1, the first region 18a may extend along a first plane (X-Y plane) crossing the first direction D1. For example, the first region 18a being one continuous layered may be provided.

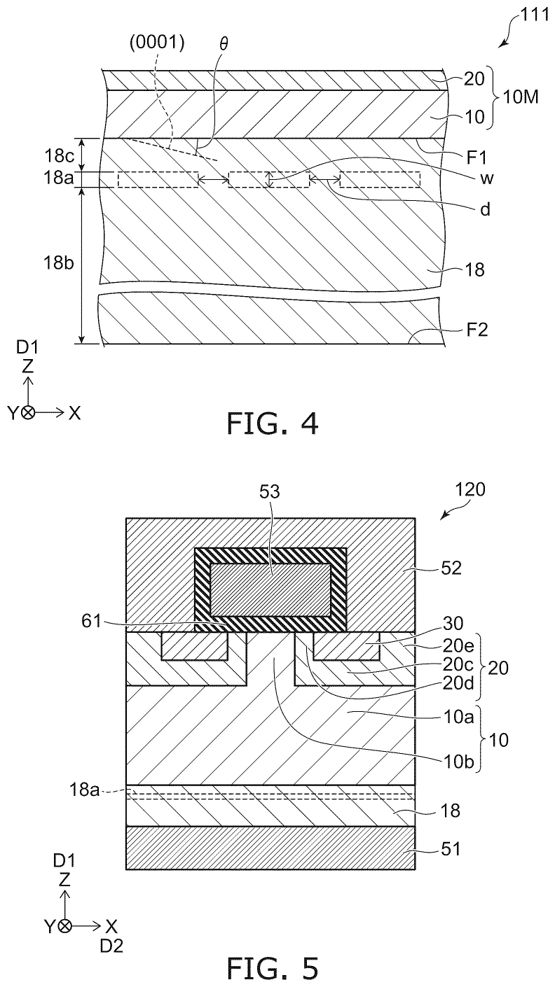

FIG. 4 is a schematic cross-sectional view illustrating a wafer according to the first embodiment.

As shown in FIG. 4, in a wafer 111 according to the embodiment, the substrate 18 includes a plurality of first regions 18a. The configuration of the wafer 111 except for this may be the same as the configuration of the wafer 110.

In the wafer 111, the plurality of first regions 18a are provided along the plane (for example, the X-Y plane) that crosses the first direction D1. The plurality of first regions 18a may be, for example, island-shaped. The plurality of first regions 18a may be, for example, striped.

An angle between the (0001) plane of the substrate 18 and the first face F1 is defined as angle θ. A thickness of one of the plurality of first regions 18a along the first direction D1 is defined as a thickness d. A distance between the plurality of first regions 18a along a crossing direction crossing the first direction D1 is defined as a distance w. The angle θ, the thickness d, and the distance w may satisfy the relationship w<(d/tanθ).

Thereby, it is possible to suppress the BPD in the second region 18b from passing between the plurality of first regions 18a and extending upward. For example, the BPD in the second region 18b collides with any one of the plurality of first regions 18a. When the BPD collides with any one of the plurality of first regions 18a, expansion of stacking faults starting from the BPD is suppressed.

The angle θ may be, for example, not less than 1 degree and not more than 10 degrees. The angle θ corresponds to the offcut angle.

### Second Embodiment

FIG. 5 is a schematic cross-sectional view illustrating a semiconductor device according to the second embodiment.

As shown in FIG. 5, a semiconductor device 120 according to the embodiment includes the substrate 18 of the wafer (wafer 110 in this example) according to the first embodiment. The semiconductor device 120 may include the substrate 18 of the wafer 111.

For example, the semiconductor device 120 includes wafer 110, a third silicon carbide region 30, a first electrode 51, a second electrode 52, a third electrode 53, and an insulating member 61. The wafer 110 includes the substrate 18 and the silicon carbide member 10M (first silicon carbide region 10 and second silicon carbide region 20).

The first silicon carbide region 10 includes at least one selected from the group consisting of nitrogen, phosphorus, and arsenic. The second silicon carbide region 20 includes at least one selected from the group consisting of boron, aluminum, and gallium. The third silicon carbide region 30 includes at least one selected from the group consisting of nitrogen, phosphorus, and arsenic.

A direction from the first electrode 51 to the second electrode 52 is along the first direction D1. The first silicon carbide region 10 includes a first partial region 10a and a second partial region 10b. The second silicon carbide region 20 includes a third partial region 20c and a fourth partial region 20d. The third partial region 20c is located between the first partial region 10a and the third silicon carbide region 30 in first direction D1. A direction from the second partial region 10b to the third electrode 53 is along the first direction D1. The fourth partial region 20d is located between the second partial region 10b and the third silicon carbide region 30 in a second direction D2 crossing the first direction D1.

The first electrode 51 is electrically connected to the substrate 18. The second electrode 52 is electrically connected to third silicon carbide region 30. The insulating member 61 is provided between the second partial region 10b and the third electrode 53.

In this example, the second silicon carbide region 20 further includes a fifth partial region 20e. The third silicon carbide region 30 is located between the fourth partial region 20d and the fifth partial region 20e in the second direction D2. The second electrode 52 is electrically connected to the fifth partial region 20e.

For example, a current flowing between the first electrode 51 and the second electrode 52 can be controlled by a potential of the third electrode 53. A potential of the third electrode 53 may be, for example, a potential based on a potential of the second electrode 52. The third electrode 53 functions as a gate electrode. The semiconductor device 120 is, for example, a transistor.

In the semiconductor device 120, the substrate 18 may be of n-type. In this case, the semiconductor device 120 is a MOS type FET. For example, first silicon carbide region 10 corresponds to, for example, a drift layer. The second silicon carbide region 20 corresponds to, for example, a p-well. The third silicon carbide region 30 corresponds to, for example, an n⁺ source.

In the embodiment, the substrate 18 may be of p-type. In this case, the semiconductor device 120 is an IGBT (Insulated Gate Bipolar Transistor).

The wafer 110 (or the wafer 111) according to the embodiment may be applied to a diode or the like.

The embodiments may include the following Technical proposals:

### (Technical Proposal 1)

A wafer, comprising:
a substrate including silicon carbide,
the substrate including a first face and a second face,
the substrate including
   a first region between the second face and the first face in a first direction from the second face to the first face,
   a second region between the second face and the first region in the first direction, and
   a third region between the first region and the first face in the first direction,
the substrate including nitrogen,
the first region including a first element including at least one selected from the group consisting of phosphorus and arsenic, and
a first concentration of the first element in the first region being higher than a second concentration of the first element in the second region, and higher than a third concentration of the first element in the third region.

### (Technical Proposal 2)

The wafer according to Technical proposal 1, wherein
the substrate includes a first position, a second position and a third position,
the first position is included in the first region,
the second position is between the second face and the first position in the first direction,
the third position is between the first position and the first face in the first direction,
in the first direction, a concentration of the first element in the substrate is at a first peak value at the first position,
a concentration of the first element at the second position is 1/10 of the first peak value,
a concentration of the first element at the third position is 1/10 of the first peak value, and
a distance along the first direction between the second position and the third position is not less than 0.2 μm and not more than 0.4 μm.

### (Technical Proposal 3)

The wafer according to Technical proposal 1, wherein
a first peak value of the first element in the substrate in the first direction is not less than 1×10¹⁶ cm⁻³ and not more than 1×10¹⁸ cm⁻³.

### (Technical Proposal 4)

The wafer according to any one of Technical proposals 1-3, wherein
the first region includes a bond between silicon and the first element.

### (Technical Proposal 5)

The wafer according to any one of Technical proposals 1-4, wherein
the substrate further includes a fourth region including the first face,
the third region is located between the first region and the fourth region in the first direction, and
a fourth concentration of the first element in the fourth region is higher than the third concentration.

### (Technical Proposal 6)

The wafer according to any one of Technical proposals 1-5, wherein
the first concentration is 50 times or more the third concentration.

### (Technical Proposal 7)

A wafer, comprising:
a substrate including silicon carbide,
the substrate including a first face and a second face,
the substrate including
   a first region between the second face and the first face in a first direction from the second face to the first face,
   a second region between the second face and the first region in the first direction, and
   a third region between the first region and the first face in the first direction,
the substrate includes aluminum,
the first region including a second element including at least one selected from the group consisting of gallium and indium, and
a first concentration of the second element in the first region being higher than a second concentration of the second element in the second region, and higher than a third concentration of the second element in the third region.

### (Technical Proposal 8)

The wafer according to Technical proposal 7, wherein
the substrate includes a first position, a second position and a third position,
the first position is included in the first region,
the second position is between the second face and the first position in the first direction,
the third position is between the first position and the first face in the first direction,
in the first direction, a concentration of the second element in the substrate is at a first peak value at the first position,
a concentration of the second element at the second position is 1/10 of the first peak value,
a concentration of the second element at the third position is 1/10 of the first peak value, and
a distance along the first direction between the second position and the third position is not less than 0.2 μm and not more than 0.4 μm.

### (Technical Proposal 9)

The wafer according to Technical proposal 7, wherein
the first peak value of the second element in the substrate in the first direction is not less than 1×10¹⁶ cm⁻³ and not more than 1×10¹⁸ cm⁻³.

### (Technical Proposal 10)

The wafer according to any one of Technical proposals 7-9, wherein
the first region includes a bond between silicon and the second element.

### (Technical Proposal 11)

The wafer according to any one of Technical proposals 7-10, wherein
the substrate further includes a fourth region including the first face,
the third region is located between the first region and the fourth region in the first direction, and
a fourth concentration of the second element in the fourth region is higher than the third concentration.

### (Technical Proposal 12)

The wafer according to any one of Technical proposals 7-11, wherein
the first concentration is 50 times or more the third concentration.

### (Technical Proposal 13)

The wafer according to any one of Technical proposals 1-12, wherein
in the second region, a stacking fault is expanded by at least one of voltage application or ultraviolet irradiation, and
in the third region, the stacking fault does not substantially expand by the at least one of the voltage application or the ultraviolet irradiation.

### (Technical Proposal 14)

The wafer according to any one of Technical proposals 1-13, wherein
the first region extends along a first plane crossing the first direction.

### (Technical Proposal 15)

The wafer according to any one of Technical proposals 1-14, wherein
the substrate includes a plurality of the first regions,
the plurality of first regions are provided along a plane crossing the first direction, and
an angle θ between a (0001) plane of the substrate and the first face, a thickness d of one of the plurality of first regions along the first direction, and a distance w between the plurality of first regions along a crossing direction crossing the first direction satisfies a relationship of w<(d/tanθ).

### (Technical Proposal 16)

The wafer according to any one of Technical proposals 1-15, further comprising:
a silicon carbide member,
the silicon carbide member includes a first silicon carbide region including a third element,
the third element includes at least one selected from the group consisting of nitrogen, phosphorus, and arsenic, and
the first face is located between the second face and the first silicon carbide region.

### (Technical Proposal 17)

The wafer according to Technical proposal 16, wherein
the silicon carbide member further includes a second silicon carbide region including a fourth element,
the first silicon carbide region is located between the substrate and the second silicon carbide region in the first direction, and
the fourth element includes at least one selected from the group consisting of boron, aluminum, and gallium.

### (Technical Proposal 18)

A semiconductor device, comprising:
the wafer according to any one of Technical proposals 1-17.

### (Technical Proposal 19)

A semiconductor device, comprising:
the wafer according to Technical proposal 17;
a third silicon carbide region;
a first electrode;
a second electrode;
a third electrode; and
an insulating member,
the third silicon carbide region includes at least one selected from the group consisting of nitrogen, phosphorus, and arsenic,
a direction from the first electrode to the second electrode is along the first direction,
the first silicon carbide region includes a first partial region and a second partial region,
the second silicon carbide region includes a third partial region and a fourth partial region,
the third partial region being located between the first partial region and the third silicon carbide region in the first direction,
a direction from the second partial region to the third electrode being along the first direction,
the fourth partial region being located between the second partial region and the third silicon carbide region in a second direction crossing the first direction,
the first electrode being electrically connected to the substrate,
the second electrode being electrically connected to the third silicon carbide region, and
the insulating member being located between the second partial region and the third electrode.

### (Technical Proposal 20)

The semiconductor device according to Technical proposal 19, wherein
the second silicon carbide region further includes a fifth partial region,
the third silicon carbide region is located between the fourth partial region and the fifth partial region in the second direction, and
the second electrode is electrically connected to the fifth partial region.

According to the embodiment, it is possible to provide a wafer and a semiconductor device whose characteristics can be stabilized.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafers and the semiconductor devices such as substrate, silicon carbide members, silicon carbide regions, electrodes, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers and all semiconductor devices practicable by an appropriate design modification by one skilled in the art based on the wafers and the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a substrate including silicon carbide,
the substrate including a first face and a second face,
the substrate including
a first region between the second face and the first face in a first direction from the second face to the first face,
a second region between the second face and the first region in the first direction, and
a third region between the first region and the first face in the first direction,
the substrate including nitrogen,
the first region including a first element including at least one selected from the group consisting of phosphorus and arsenic, and
a first concentration of the first element in the first region being higher than a second concentration of the first element in the second region, and higher than a third concentration of the first element in the third region.

2. The wafer according to claim 1, wherein
the substrate includes a first position, a second position and a third position,
the first position is included in the first region,
the second position is between the second face and the first position in the first direction,
the third position is between the first position and the first face in the first direction,
in the first direction, a concentration of the first element in the substrate is at a first peak value at the first position,
a concentration of the first element at the second position is 1/10 of the first peak value,
a concentration of the first element at the third position is 1/10 of the first peak value, and
a distance along the first direction between the second position and the third position is not less than 0.2 μm and not more than 0.4 μm.

3. The wafer according to claim 1, wherein
a first peak value of the first element in the substrate in the first direction is not less than 1×10¹⁶ cm⁻³ and not more than 1×10¹⁸ cm⁻³.

4. The wafer according to claim 1, wherein
the first region includes a bond between silicon and the first element.

5. The wafer according to claim 1, wherein
the substrate further includes a fourth region including the first face,
the third region is located between the first region and the fourth region in the first direction, and
a fourth concentration of the first element in the fourth region is higher than the third concentration.

6. The wafer according to claim 1, wherein
the first concentration is 50 times or more the third concentration.

7. A wafer, comprising:
a substrate including silicon carbide,
the substrate including a first face and a second face,
the substrate including
a first region between the second face and the first face in a first direction from the second face to the first face,
a second region between the second face and the first region in the first direction, and
a third region between the first region and the first face in the first direction,
the substrate includes aluminum,
the first region including a second element including at least one selected from the group consisting of gallium and indium, and
a first concentration of the second element in the first region being higher than a second concentration of the second element in the second region, and higher than a third concentration of the second element in the third region.

8. The wafer according to claim 7, wherein
the substrate includes a first position, a second position and a third position,
the first position is included in the first region,
the second position is between the second face and the first position in the first direction,
the third position is between the first position and the first face in the first direction,
in the first direction, a concentration of the second element in the substrate is at a first peak value at the first position,
a concentration of the second element at the second position is 1/10 of the first peak value,
a concentration of the second element at the third position is 1/10 of the first peak value, and
a distance along the first direction between the second position and the third position is not less than 0.2 μm and not more than 0.4 μm.

9. The wafer according to claim 7, wherein
the first peak value of the second element in the substrate in the first direction is not less than 1×10¹⁶ cm⁻³ and not more than 1×10¹⁸ cm⁻³.

10. The wafer according to claim 7, wherein
the first region includes a bond between silicon and the second element.

11. The wafer according to claim 7, wherein
the substrate further includes a fourth region including the first face,
the third region is located between the first region and the fourth region in the first direction, and
a fourth concentration of the second element in the fourth region is higher than the third concentration.

12. The wafer according to claim 7, wherein
the first concentration is 50 times or more the third concentration.

13. The wafer according to claim 1, wherein
in the second region, a stacking fault is expanded by at least one of voltage application or ultraviolet irradiation, and
in the third region, the stacking fault does not substantially expand by the at least one of the voltage application or the ultraviolet irradiation.

14. The wafer according to claim 1, wherein
the first region extends along a first plane crossing the first direction.

15. The wafer according to claim 1, wherein
the substrate includes a plurality of the first regions,
the plurality of first regions are provided along a plane crossing the first direction, and
an angle θ between a (0001) plane of the substrate and the first face, a thickness d of one of the plurality of first regions along the first direction, and a distance w between the plurality of first regions along a crossing direction crossing the first direction satisfies a relationship of w<(d/tanθ).

16. The wafer according to claim 1, further comprising:
a silicon carbide member,
the silicon carbide member includes a first silicon carbide region including a third element,
the third element includes at least one selected from the group consisting of nitrogen, phosphorus, and arsenic, and
the first face is located between the second face and the first silicon carbide region.

17. The wafer according to claim 16, wherein
the silicon carbide member further includes a second silicon carbide region including a fourth element,
the first silicon carbide region is located between the substrate and the second silicon carbide region in the first direction, and
the fourth element includes at least one selected from the group consisting of boron, aluminum, and gallium.

18. A semiconductor device, comprising:
the wafer according to claim 1.

19. A semiconductor device, comprising:
the wafer according to claim 17;
a third silicon carbide region;
a first electrode;
a second electrode;
a third electrode; and
an insulating member,
the third silicon carbide region includes at least one selected from the group consisting of nitrogen, phosphorus, and arsenic,
a direction from the first electrode to the second electrode is along the first direction,
the first silicon carbide region includes a first partial region and a second partial region,
the second silicon carbide region includes a third partial region and a fourth partial region,
the third partial region being located between the first partial region and the third silicon carbide region in the first direction,
a direction from the second partial region to the third electrode being along the first direction,
the fourth partial region being located between the second partial region and the third silicon carbide region in a second direction crossing the first direction,
the first electrode being electrically connected to the substrate,
the second electrode being electrically connected to the third silicon carbide region, and
the insulating member being located between the second partial region and the third electrode.

20. The semiconductor device according to claim 19, wherein
the second silicon carbide region further includes a fifth partial region,
the third silicon carbide region is located between the fourth partial region and the fifth partial region in the second direction, and
the second electrode is electrically connected to the fifth partial region.
